(19) United States
(12) Patent Application Publication
(10) Pub. No.: US 2017/0192072 A1
(43) Pub. Date: Jul. 6, 2017

(54) METHODS AND SYSTEMS FOR CORRECTING K-SPACE TRAJECTORIES

(71) Applicant: General Electric Company, Schenectady, NY (US)

(72) Inventors: Derek Allan Seeber, Florence, SC (US); Edwin Lawrence Legall, Florence, SC (US)

(21) Appl. No.: 14/989,024

(22) Filed: Jan. 6, 2016

(51) Int. Cl. G01R 33/48; G01R 33/58

(52) U.S. Cl. CPC G01R 33/4818; G01R 33/58

(57) ABSTRACT

Various methods and systems are provided for correcting k-space trajectories. In one embodiment, a system comprises a coil configured to generate a magnetic field, a plurality of magnetic field probes positioned at the coil and configured to measure the magnetic field, and a controller communicatively coupled to the plurality of magnetic field probes and including instructions stored in non-transitory memory that when executed cause the controller to: receive measurements of the magnetic field from the plurality of magnetic field probes; calculate corrections to positions of acquired magnetic resonance signals in spatial-frequency space based on the received measurements; apply the corrections to the positions to generate corrected magnetic resonance signals; and reconstruct an image from the corrected magnetic resonance signals. In this way, image artifacts caused by eddy currents can be reduced.

### FIELD

Embodiments of the subject matter disclosed herein relate to magnetic resonance imaging (MM), and more particularly, to correcting k-space trajectories.

### BACKGROUND

Magnetic resonance imaging (MRI) is a medical imaging modality that can create pictures of the inside of a human body without using x-rays or other ionizing radiation. MRI uses a powerful magnet to create a strong, uniform, static magnetic field. When a human body, or part of a human body, is placed in the magnetic field, the nuclear spins associated with the hydrogen nuclei in tissue water become polarized, wherein the magnetic moments associated with these spins become preferentially aligned along the direction of the magnetic field, resulting in a small net tissue magnetization along that axis. MM systems also include gradient coils that produce smaller amplitude, spatially-varying magnetic fields with orthogonal axes to spatially encode the MR signal by creating a signature resonance frequency at each location in the body. Radio frequency (RF) coils are then used to create pulses of RF energy at or near the resonance frequency of the hydrogen nuclei, which add energy to the nuclear spin system. As the nuclear spins relax back to their rest energy state, they release the absorbed energy in the form of an RF signal. This signal, also referred to as an MR signal, is detected by the MRI system and is transformed into an image using a computer and known reconstruction algorithms.

During an MRI scan, the MRI system uses time-varying gradient magnetic fields to encode spatial position in the received MR signal. If the gradient fields are linear, it can be shown that the received MR signal is equal to the value of the Fourier transform of the imaged object at some spatial frequency, and the received signal over time maps to a trajectory through spatial-frequency space, or k-space. The trajectory path is determined by the time integral of the applied gradient waveforms. Each data point of the MR signal indicates the phase and amplitude of a spatial frequency and a full scan yields a set of observed data points that specify the MR image as the sum of these weighted spatial frequencies. More succinctly, a complete set of MRI data samples k-space sufficiently to allow reconstruction of the imaged object via the inverse Fourier transform.

The time variance of the gradient magnetic fields can induce substantial eddy currents in a conducting structure of the MRI system. These eddy currents in turn generate additional magnetic fields that tend to prevent the gradient magnetic fields from changing, and as a result the eddy currents affect the k-space trajectory. K-space trajectory infidelity due to such eddy current effects and other hardware imperfections will blur and distort the reconstructed images. Even with shielded gradients and eddy current compensation techniques of current scanners, the deviation between the actual k-space trajectory and the requested trajectory remains a major reason for image artifacts in non-Cartesian MRI.

To reduce the eddy current effect, manufacturers have active shielding and pre-emphasis filters in current scanners to eliminate most of the errors. However, the residual error can still cause severe image artifacts, especially in non-Cartesian scanning such as radial and spiral imaging.

### BRIEF DESCRIPTION

In one embodiment, a system comprises a coil configured to generate a magnetic field, a plurality of magnetic field probes positioned at the coil and configured to measure the magnetic field, and a controller communicatively coupled to the plurality of magnetic field probes and including instructions stored in non-transitory memory that when executed cause the controller to: receive measurements of the magnetic field from the plurality of magnetic field probes; calculate corrections to positions of acquired magnetic resonance signals in spatial-frequency space based on the received measurements; apply the corrections to the positions to generate corrected magnetic resonance signals; and reconstruct an image from the corrected magnetic resonance signals. In this way, image artifacts caused by eddy currents can be reduced.

It should be understood that the brief description above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The present invention will be better understood from reading the following description of non-limiting embodiments, with reference to the attached drawings, wherein below:

FIG. 1 is a block diagram of an exemplary imaging system according to an embodiment of the invention;

FIG. 2 is a block diagram illustrating magnetic field probes positioned at a gradient coil according to an embodiment of the invention;

FIG. 3 is a block diagram illustrating magnetic field probes positioned at a body coil according to an embodiment of the invention;

FIG. 4 is a simplified perspective view of an exemplary coil with a plurality of magnetic field probes positioned thereto according to an embodiment of the invention.

FIG. 5 is a high-level flow chart illustrating an example method for correcting k-space trajectories according to an embodiment of the invention; and

FIG. 6 is a graph illustrating example k-space trajectories according to an embodiment of the invention.

### DETAILED DESCRIPTION

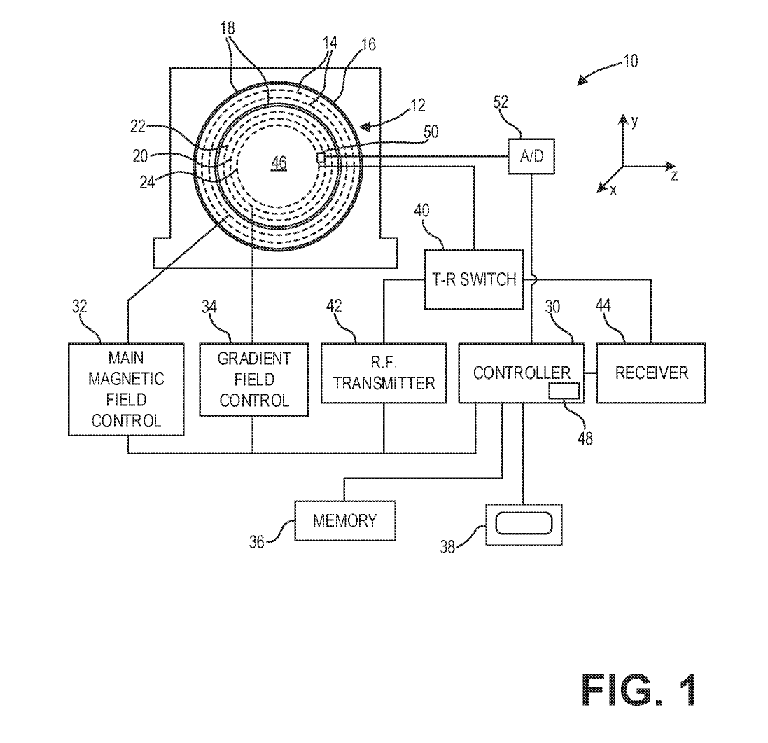

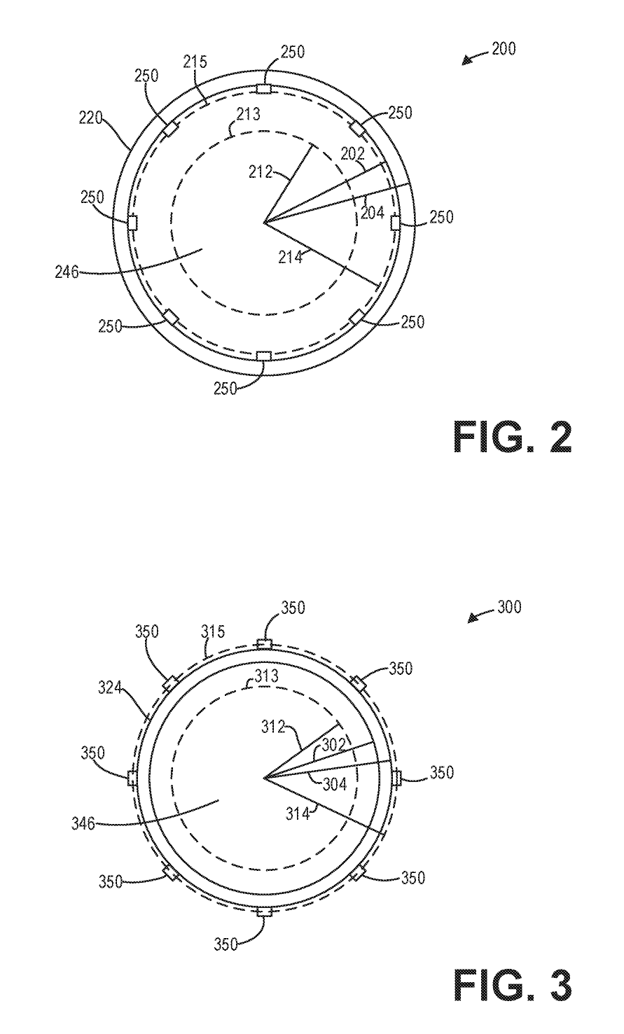

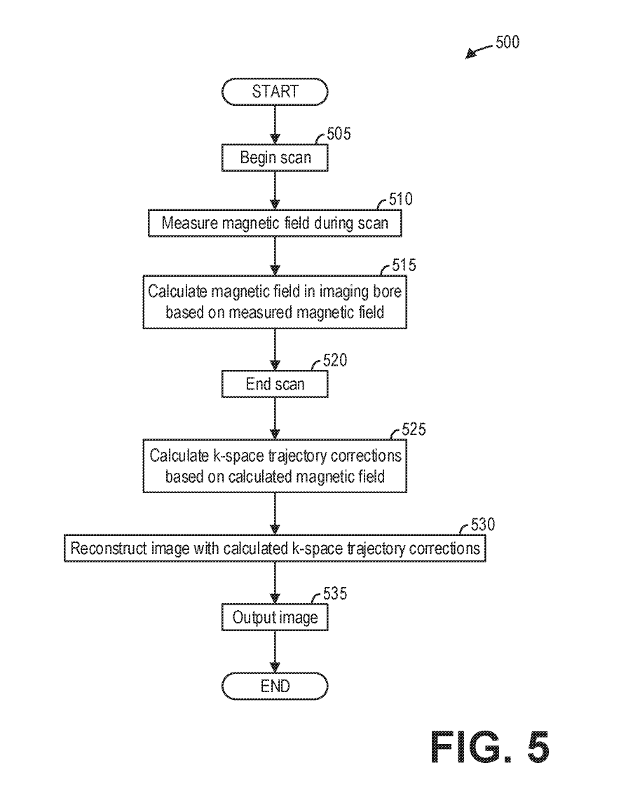

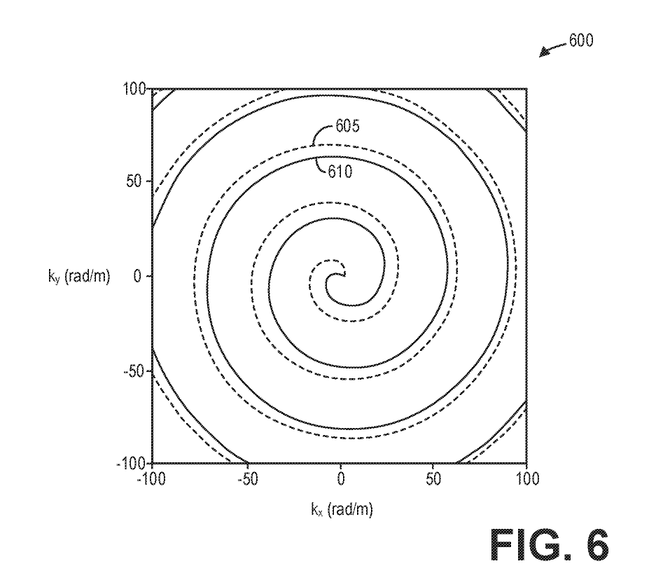

The following description relates to various embodiments of MRI systems. In particular, methods and systems are provided for correcting k-space trajectories in an MRI system, such as the MM system depicted in FIG. 1. As shown in FIGS. 2-4, a plurality of magnetic field probes are positioned at an electromagnetic coil, such as a gradient coil or an RF coil, of the MRI system. A method for correcting k-space trajectories, such as the method shown in FIG. 5, includes measuring the magnetic field with the plurality of magnetic field probes during a scan, and correcting the k-space trajectory of the data acquisition based on the measured magnetic field. An image reconstructed with the corrected k-space trajectory will include fewer image artifacts caused by eddy current effects and other hardware imperfections. As an illustrative example, FIG. 6 shows an actual k-space trajectory compared to an expected k-space trajectory.

FIG. 1 illustrates an example imaging system 10. The imaging system 10 generally includes a superconducting magnet assembly 12 that includes a superconducting magnet 14. The superconducting magnet 14 is formed from a plurality of magnetic coils supported on a magnet coil support or coil former. In one embodiment, the superconducting magnet assembly 12 may also include a thermal shield 16. A vessel 18 (also referred to as a cryostat) surrounds the superconducting magnet 14, and the thermal shield 16 surrounds the vessel 18. The vessel 18 is typically filled with liquid helium to cool the coils of the superconducting magnet 14. A thermal insulation (not shown) may be provided surrounding the outer surface of the vessel 18. The imaging system 10 also includes a main gradient coil 20, a shield gradient coil 22, and an RF transmit coil 24. The imaging system 10 also generally includes a controller 30, a main magnetic field control 32, a gradient field control 34, a memory 36, a display device 38, a transmit-receive (T-R) switch 40, an RF transmitter 42 and a receiver 44.

In operation, a body of an object, such as a patient (not shown), or a phantom to be imaged, is placed in a bore 46 on a suitable support, for example, a motorized table (not shown) or other patient table. The superconducting magnet 14 produces a uniform and static magnetic main magnetic field B₁ across the bore 46. The strength of the electromagnetic field in the bore 46 and correspondingly in the patient, is controlled by the controller 30 via the main magnetic field control 32, which also controls a supply of energizing current to the superconducting magnet 14.

The main gradient coil 20, which may include one or more gradient coil elements, is provided so that a magnetic gradient can be imposed on the magnetic field B₁ in the bore 46 in any one or more of three orthogonal directions x, y, and z. The main gradient coil 20 is energized by the gradient field control 34 and is also controlled by the controller 30.

The RF transmit coil 24, which may include a plurality of coils (e.g., resonant surface coils), is arranged to transmit magnetic pulses and/or optionally simultaneously detect MR signals from the patient, if receive coil elements are also provided. The RF transmit coil 24 and a receive surface coil, if provided, may be selectably interconnected to one of the RF transmitter 42 or receiver 44, respectively, by the T-R switch 40. The RF transmitter 42 and T-R switch 40 are controlled by the controller 30 such that RF field pulses or signals are generated by the RF transmitter 42 and selectively applied to the patient for excitation of magnetic resonance in the patient.

Following application of the RF pulses, the T-R switch 40 is again actuated to decouple the RF transmit coil 24 from the RF transmitter 42. The detected MR signals are in turn communicated to the controller 30. The controller 30 includes a processor 48 that controls the processing of the MR signals to produce signals representative of an image of the patient. The processed signals representative of the image are also transmitted to the display device 38 to provide a visual display of the image. Specifically, the MR signals fill or form a k-space that is Fourier transformed to obtain a viewable image which may be viewed on the display device 38.

As mentioned above, imaging system 10 may include one or more magnetic field probes 50 configured to measure the magnetic field within the bore 46. For example, a plurality of magnetic field probes 50 may be physically coupled to one or more components of the imaging system 10, including but not limited to the superconducting magnet assembly 12, the superconducting magnet 14, the thermal shield 16, the vessel 18, the gradient coil 20, the shield gradient coil 22, the RF transmit coil 24, and/or any suitable component. As depicted, the plurality of magnetic field probes 50 may be communicatively coupled to the controller 30, and may transmit measurements of the magnetic field within the imaging bore 46 to the controller 30. To facilitate the communication of the magnetic field measurements from the magnetic field probes 50 to the controller 30, the MRI system 10 may further include at least one analog-digital (A/D) converter 52 to convert analog measurements produced by the magnetic field probes 50 into digital signals provided to the controller 30. The magnetic field probes 50 may comprise any suitable device for measuring the strength (and optionally, the direction) of a magnetic field, and so may comprise, but are not limited to, magnetic loops, magnetometers, Hall effect sensors, and so on.

As described further herein, the controller 30 may use measurements of the magnetic field, received from the plurality of magnetic field probes 50 during a scan, to adjust or correct the MR signals in k-space to account for deviations of the measured magnetic field from the assumed magnetic field. As known in the art, k-space is a grid of raw data of the form (kₓ, k_{y}) obtained directly from the MR signal, where values correspond to spatial frequencies of the MR image. The k-space trajectory path is determined by the time integral of the applied gradient waveforms. In other words, the k-space trajectory path is proportional to the accumulated area under the gradient waveforms, for example:

kₓ(t)=A∫Gₓ(τ)dτ

k_{y}(t)=A∫G_{y}(τ)dτ

where A is a constant, kₓ(t) is the k-space position in the x direction over time, k_{y}(t) is the k-space position in the y direction over time, Gₓ(τ) is the gradient field in the x direction over time, and G_{y}(τ) is the gradient field in the y direction over time. In this way, the gradient fields move the data acquisition along a trajectory through k-space. Therefore, to account for k-space trajectory infidelity during a scan, the controller 30 can use measurements of the magnetic fields to correct deviations in the k-space trajectory. In this way, image artifacts caused by errors in the gradient fields (e.g., caused by eddy currents) can be reduced.

As mentioned above, the plurality of magnetic field probes 50 are preferably positioned to measure the magnetic field within the imaging bore 46. To that end, the plurality of magnetic field probes 50 may be attached to or integrally formed (i.e., embedded) within one or more components of the MRI system 10. For example, FIG. 2 shows a cross-sectional view 200 of an exemplary gradient coil 220 with a plurality of magnetic field probes 250 attached thereto according to an embodiment. In particular, the cylindrical gradient coil 220 includes an inner diameter (indicated by the inner radius 202) and an outer diameter (indicated by the outer radius 204), and the plurality of magnetic field probes 250 are positioned at the inner radius 202 of the gradient coil 220. In some examples, the plurality of magnetic field probes 250 may be embedded in the gradient coil 220.

As mentioned above, the plurality of magnetic field probes 250 measure the magnetic field at the boundary of a volume 215 with a radius 214, and these measurements may be used to calculate the magnetic field within the imaging bore 246. Specifically, the magnetic field within a volume 213 with a radius 212 may be calculated based on measurements of the magnetic field at the boundary of volume 215, where the radius 214 of the volume 215 is larger than the radius 212 of the volume 213 enclosing at least a portion of the imaging bore 246 wherein a subject may be placed during a scan. In examples wherein the plurality of magnetic field probes 250 are positioned at the inner radius 202 of the gradient coil 220, the radius 214 of the volume 215 may be smaller than the inner radius 202 of the gradient coil 220. In examples wherein the plurality of magnetic field probes 250 are embedded within the gradient coil 220 (preferably towards the inner radius 202 rather than towards the outer radius 204), the radius 214 may be equal to or larger than the inner radius 202 but smaller than the outer radius 204.

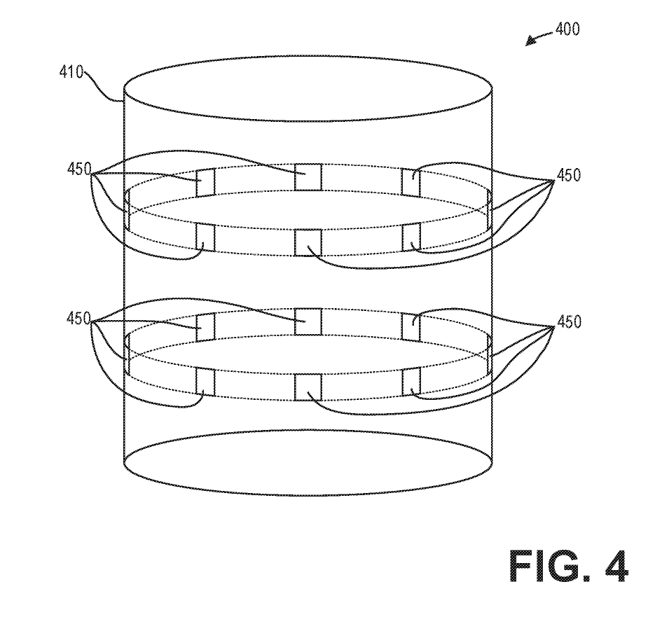

As another example, FIG. 3 shows a cross-sectional view 300 of an exemplary RF coil 324 with a plurality of magnetic field probes 350 attached thereto according to an embodiment. In particular, the cylindrical RF coil 324 includes an inner diameter (indicated by the inner radius 302) and an outer diameter (indicated by the outer radius 304), and the plurality of magnetic field probes 350 are positioned at the outer radius 304 of the RF coil 324. In some examples, the plurality of magnetic field probes 350 may be embedded in the RF coil 324.

As mentioned above, the plurality of magnetic field probes 350 measure the magnetic field at the boundary of a volume 315 with a radius 314, and these measurements may be used to calculate the magnetic field within the imaging bore 346. Specifically, the magnetic field within a volume 313 with a radius 312 may be calculated based on measurements of the magnetic field at the boundary of volume 315, where the radius 314 of the volume 315 is larger than the radius 312 of the volume 313 enclosing at least a portion of the imaging bore 346 wherein a subject may be positioned during a scan. In examples wherein the plurality of magnetic field probes 350 are positioned at the outer radius 304 of the RF coil 324, the radius 314 of the volume 315 may be larger than the outer radius 304 of the RF coil 324. In examples wherein the plurality of magnetic field probes 350 are embedded within the RF coil 324 (preferably towards the outer radius 304 rather than towards the inner radius 302), the radius 314 may be equal to or smaller than the outer radius 304 but larger than the inner radius 302.

Note that in the example embodiments depicted in FIGS. 2 and 3, the plurality of magnetic field probes 250 and 350 are symmetrically distributed in a ring around the coil. In this way, the magnetic field may be sampled at a plurality of points along the boundaries of volumes 215 and 315. As described further herein, in some embodiments a plurality of such rings of symmetrically-positioned magnetic field probes may be attached to or embedded within an MRI system component such as a gradient or RF coil.

FIG. 4 shows a side view 400 of a cylindrical MRI system component 410 with a plurality of magnetic field probes 450 attached thereto according to an embodiment. In particular, the plurality of magnetic field probes 450 are symmetrically arranged around the cylindrical coil 410 in multiple rings or rows (indicated by the dashed lines). The cylindrical coil 410 may comprise, as non-limiting examples, an RF coil (e.g., RF coil 24) or a gradient coil (e.g., gradient coils 20 and/or 22). In this way, the plurality of magnetic field probes 450 may sample the magnetic field at different positions in the axial direction.

It should be appreciated that the gradient coil 220, the RF coil 324, and the coil 410 described above with regard to FIGS. 2-4 are shown in simplified form and may include additional components not shown, including but not limited to shim bars, shielding, and so on.

FIG. 5 shows a high-level flow chart illustrating an example method 500 for correcting k-space trajectories according to an embodiment of the invention. In particular, method 500 relates to measuring the magnetic field within an imaging bore during a scan, and reconstructing an image with corrected k-space trajectories calculated based on the measured magnetic field. Method 500 may be described with regard to the systems and components depicted in FIGS. 1-4, though it should be understood that the method may be implemented with other systems and components without departing from the scope of the present disclosure.

Method 500 begins at 505. At 505, method 500 begins scanning. Scanning comprises generating a static magnetic field within the imaging bore (e.g., via main magnet 14), generating time-varying and spatially-varying gradient magnetic fields within the imaging bore (e.g., via gradient coils 20 and 22), generating RF pulses (e.g., via RF coil 24) applied to a subject positioned within the imaging bore to excite nuclei within the subject, and acquiring MR signals (e.g., via RF coil 24 or an additional receive coil) generated by the excitation of the nuclei along one or more k-space trajectories.

At 510, method 500 measures the magnetic field during the scan. The magnetic field may be measured using one or more magnetic field probes positioned within the imaging apparatus. For example, a plurality of magnetic field probes such as those depicted in FIGS. 2-4 may measure or sample the magnetic field. Method 500 records the magnetic field measurements acquired via the magnetic field probes over time and may, for example, store the measurements in local memory.

At 515, method 500 calculates the magnetic field within the imaging bore based on the magnetic field measurements. If the magnetic field is measured at the boundary of a volume enclosing the imaging bore, for example as described herein above with regard to FIGS. 2-4, then method 500 calculates the magnetic field within the volume or within a smaller volume based on the measurements. To that end, calculating the magnetic field based on the magnetic field measurements may comprise, as a non-limiting example, applying a transfer function to the magnetic field measurements. For example, the magnetic field within the imaging bore may be expressed as:

B_{bore}(t)=T(t)B_{boundary}(t)

where B_{bore}(t) is the magnetic field within the imaging bore (e.g., within the volume) over time, B_{boundary}(t) is the magnetic field measured at the boundary of the volume over time, and T(t) is the transfer function. In some examples, the calculated magnetic field may be expressed using cylindrical harmonics as basis functions, as a non-limiting example.

At 520, method 500 ends the scan. Continuing at 525, method 500 calculates k-space trajectory corrections based on the calculated magnetic field. In some examples, calculating the k-space trajectory corrections comprises calculating a k-space trajectory based on the magnetic fields calculated at 515. In other words, the corrected k-space trajectory may be calculated by integrating the calculated gradient waveforms over time as discussed herein above. In other examples, the calculated magnetic field may be proportional to the commanded magnetic field, and so calculating a corrected k-space trajectory may comprise multiplying the expected (i.e., commanded) k-space trajectory by the proportional factor.

As an example, FIG. 6 shows a graph 600 illustrating example k-space trajectories. In particular, the k-space trajectory 605 comprises the expected k-space trajectory while the k-space trajectory 610 comprises the measured k-space trajectory. Although spiral k-space trajectories are depicted, it should be appreciated that the systems and methods described herein may alternatively or additionally use Cartesian, echo-planar, and/or radial k-space trajectories. If the image is reconstructed from the acquired MR signals in accordance with the expected k-space trajectory 605, image artifacts may occur because the positions of the MR signals in the expected k-space trajectory 605 substantially differ from the actual k-space trajectory 610. Correcting the k-space trajectory comprises adjusting the positions of acquired MR signals to match the actual k-space trajectory rather than the expected k-space trajectory.

Referring again to FIG. 5, method 500 continues to 530 after calculating the k-space trajectory corrections. At 530, method 500 reconstructs an image with the calculated k-space trajectory corrections. Reconstructing an image comprises, for example, inverse Fourier transforming the data in k-space. In some examples, reconstructing an image comprises inverse Fourier transforming the data and additionally back-projecting the transformed data. By using the measured k-space trajectory rather than the expected k-space trajectory, image artifacts in the reconstructed image caused by k-space trajectory infidelity may be reduced, thereby improving image quality.

At 535, method 500 outputs the image. Outputting the image may comprise, for example, outputting the image to a display device (e.g., display device 38) for display to a user of the imaging system. Additionally or alternatively, method 500 may output the image to memory (e.g., memory 36) for retrieval and review at a later time. Method 500 then ends.

In some examples, the method may additionally calibrate one or more of the controller, the gradient field control, the RF transmitter, and the receiver based on the measured magnetic field. For example, if the same k-space trajectory corrections are calculated and applied during every scan, the method may calibrate one or more components of the MR system so that fewer corrections may be applied in subsequent scans. In this way, the magnetic field measurements may be used for feed-forward control (for subsequent scans) in addition to or as an alternative to feed-back control during a scan.

The technical effect of the disclosure may include the measurement of magnetic fields within an imaging bore during a scan. Another technical effect of the disclosure may include the display of an image reconstructed with a corrected k-space trajectory, wherein the corrected k-space trajectory is corrected based on magnetic field measurements acquired during the scan. Another technical effect of the disclosure may include the reduction of image artifacts caused by eddy currents and hardware malfunctions. Yet another technical effect of the disclosure may include the calibration of an imaging system based on magnetic field measurements acquired during a scan.

In one embodiment, a system comprises a coil configured to generate a magnetic field, a plurality of magnetic field probes positioned at the coil and configured to measure the magnetic field, and a controller communicatively coupled to the plurality of magnetic field probes. The controller includes instructions stored in non-transitory memory that when executed cause the controller to: receive measurements of the magnetic field from the plurality of magnetic field probes; calculate corrections to positions of acquired magnetic resonance signals in spatial-frequency space based on the received measurements; apply the corrections to the positions to generate corrected magnetic resonance signals; and reconstruct an image from the corrected magnetic resonance signals. In a first example of the system, the coil comprises a cylindrical structure at least partially enclosing and defining an imaging bore, and the plurality of magnetic field probes are positioned at a surface of the coil to measure the magnetic field within the imaging bore. In a second example of the system optionally including the first example, the plurality of magnetic field probes are evenly spaced around a circumference of the cylindrical structure to form at least one ring of magnetic field probes. In a third example of the system optionally including one or more of the first and second examples, the coil comprises a gradient coil, and the plurality of magnetic field probes are positioned at an inner diameter of the gradient coil. In a fourth example of the system optionally including one or more of the first through third examples, the coil comprises a radio frequency coil, and the plurality of magnetic field probes are positioned at an outer diameter of the radio frequency coil. In a fifth example of the system optionally including one or more of the first through fourth examples, the system further comprises a display device, and the instructions further cause the controller to output the image to the display device for display. In a sixth example of the system optionally including one or more of the first through fifth examples, the system further comprises a radio frequency receiver coil communicatively coupled to the controller and configured to detect magnetic resonance signals, wherein the instructions further cause the controller to receive the acquired magnetic resonance signals from the radio frequency receiver coil. In a seventh example of the system optionally including one or more of the first through sixth examples, the instructions further cause the controller to calculate the magnetic field at a distance away from the plurality of magnetic field probes based on the received measurements and a transfer function, and calculating the positions of the acquired magnetic resonance signals based on the received measurements comprises calculating the positions of the acquired magnetic resonance signals based on the calculated magnetic field. In an eighth example of the method optionally including one or more of the first through seventh examples, reconstructing the image comprises applying an inverse Fourier transform to the corrected magnetic resonance signals.

In a second embodiment, a method comprises, during a scan of a subject, measuring a magnetic field while acquiring data, correcting the acquired data based on the measured magnetic field, and reconstructing an image based on the corrected acquired data. In a first example of the method, the magnetic field is measured via at least one magnetic field probe positioned away from the subject, and the method further comprises calculating a strength of the magnetic field within the subject based on the measured magnetic field. In a second example of the method optionally including the first example, correcting the acquired data based on the measured magnetic field comprises calculating a trajectory of the acquired data based on the calculated strength of the magnetic field within the subject, and adjusting positions of the acquired data based on the trajectory. In a third example of the method optionally including one or more of the first and second examples, reconstructing the image comprises inverse Fourier transforming the corrected acquired data. In a fourth example of the method optionally including one or more of the first through third examples, the measurements of the magnetic field are temporally correlated with the acquired data.

In yet another embodiment, a method comprises sampling, via a plurality of magnetic field probes, a magnetic field at a boundary of a volume during a scan, calculating the magnetic field within the volume based on the sampled magnetic field, calculating a k-space trajectory based on the calculated magnetic field, and reconstructing, from magnetic resonance signals acquired during the scan, an image with the k-space trajectory. In a first example of the method, calculating the magnetic field comprises applying a transfer function to the sampled magnetic field. In a second example of the method optionally including the first example, the calculated magnetic field is expressed using cylindrical harmonics. In a third example of the method optionally including one or more of the first and second examples, the method further comprises correcting the magnetic resonance signals based on the k-space trajectory, wherein reconstructing the image comprises applying an inverse Fourier transform to the corrected magnetic resonance signals. In a fourth example of the method optionally including one or more of the first through third examples, the method further comprises outputting the image to a display device. In a fifth example of the method optionally including one or more of the first through fourth examples, the method further comprises calibrating a gradient field control based on the calculated magnetic field.

It should be noted that the various embodiments may be implemented in hardware, software, or a combination thereof. The various embodiments and/or components, for example, the modules, or components and controllers therein, also may be implemented as part of one or more computers or processors. The computer or processor may include a computing device, an input device, a display unit, and an interface, for example, for accessing the Internet. The computer or processor may include a microprocessor. The microprocessor may be connected to a communication bus. The computer or processor may also include a memory. The memory may include Random Access Memory (RAM) and Read Only Memory (ROM). The computer or processor further may include a storage device, which may be a hard drive disk or a removable storage drive such as a floppy disk drive, optical disk drive, and the like. The storage device may also be other similar means for loading computer programs or other instructions into the computer or processor.

As used herein, the term “computer” or “module” may include any processor-based or microprocessor-based system including systems using microcontrollers, reduced instruction set computers (RISC), application-specific integrated circuits (ASIC), logic circuits, and any other circuit or processor capable of executing the functions described herein. The above examples are exemplary only, and are thus not intended to limit in any way the definition and/or meaning of the term computer.

The computer or processor executes a set of instructions that are stored in one or more storage elements, in order to process input data. The storage elements may also store data or other information as desired or needed. The storage element may be in the form of an information source or a physical memory element within a processing machine.

The set of instructions may include various commands that instruct the computer or processor as a processing machine to perform specific operations such as the methods and processes of the various embodiments of the invention. The set of instructions may be in the form of a software program. The software may be in various forms such as system software or application software and which may be embodied as a tangible and non-transitory computer readable medium. Further, the software may be in the form of a collection of separate programs or modules, a program module within a larger program or a portion of a program module. The software also may include modular programming in the form of object-oriented programming. The processing of input data by the processing machine may be in response to operator commands, or in response to results of previous processing, or in response to a request made by another processing machine.

As used herein, the terms “software” and “firmware” are interchangeable, and include any computer program stored in memory for execution by a computer, including RAM, ROM, EPROM, EEPROM, and non-volatile RAM (NVRAM). The above memory types are exemplary only, and are thus not limiting as to the types of memory usable for storage of a computer program.

As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property. The terms “including” and “in which” are used as the plain-language equivalents of the respective terms “comprising” and “wherein.” Moreover, the terms “first,” “second,” and “third,” etc. are used merely as labels, and are not intended to impose numerical requirements or a particular positional order on their objects.

This written description uses examples to disclose the invention, including the best mode, and also to enable a person of ordinary skill in the relevant art to practice the invention, including making and using any devices or systems and performing any incorporated methods. The patentable scope of the invention is defined by the claims, and may include other examples that occur to those of ordinary skill in the art. Such other examples are intended to be within the scope of the claims if they have structural elements that do not differ from the literal language of the claims, or if they include equivalent structural elements with insubstantial differences from the literal languages of the claims.

1. A system, comprising:
a coil configured to generate a magnetic field;
a plurality of magnetic field probes positioned at the coil and configured to measure the magnetic field; and
a controller communicatively coupled to the plurality of magnetic field probes, the controller including instructions stored in non-transitory memory that when executed cause the controller to:
receive measurements of the magnetic field from the plurality of magnetic field probes;
calculate corrections to positions of acquired magnetic resonance signals in spatial-frequency space based on the received measurements;
apply the corrections to the positions to generate corrected magnetic resonance signals; and
reconstruct an image from the corrected magnetic resonance signals.

2. The system of claim 1, wherein the coil comprises a cylindrical structure at least partially enclosing and defining an imaging bore, and wherein the plurality of magnetic field probes are positioned at a surface of the coil to measure the magnetic field within the imaging bore.

3. The system of claim 2, wherein the plurality of magnetic field probes are evenly spaced around a circumference of the cylindrical structure to form at least one ring of magnetic field probes.

4. The system of claim 1, wherein the coil comprises a gradient coil, and wherein the plurality of magnetic field probes are positioned at an inner diameter of the gradient coil.

5. The system of claim 1, wherein the coil comprises a radio frequency coil, and wherein the plurality of magnetic field probes are positioned at an outer diameter of the radio frequency coil.

6. The system of claim 1, further comprising a display device, wherein the instructions further cause the controller to output the image to the display device for display.

7. The system of claim 1, further comprising a radio frequency receiver coil communicatively coupled to the controller and configured to detect magnetic resonance signals, wherein the instructions further cause the controller to receive the acquired magnetic resonance signals from the radio frequency receiver coil.

8. The system of claim 1, wherein the instructions further cause the controller to calculate the magnetic field at a distance away from the plurality of magnetic field probes based on the received measurements and a transfer function, and wherein calculating the positions of the acquired magnetic resonance signals based on the received measurements comprises calculating the positions of the acquired magnetic resonance signals based on the calculated magnetic field.

9. The system of claim 1, wherein reconstructing the image comprises applying an inverse Fourier transform to the corrected magnetic resonance signals.

10. A method, comprising:
during a scan of a subject, measuring a magnetic field while acquiring data;
correcting the acquired data based on the measured magnetic field; and
reconstructing an image based on the corrected acquired data.

11. The method of claim 10, wherein the magnetic field is measured via at least one magnetic field probe positioned away from the subject, and further comprising calculating a strength of the magnetic field within the subject based on the measured magnetic field.

12. The method of claim 11, wherein correcting the acquired data based on the measured magnetic field comprises calculating a trajectory of the acquired data based on the calculated strength of the magnetic field within the subject, and adjusting positions of the acquired data based on the trajectory.

13. The method of claim 12, wherein reconstructing the image comprises inverse Fourier transforming the corrected acquired data.

14. The method of claim 10, wherein the measurements of the magnetic field are temporally correlated with the acquired data.

15. A method, comprising:
sampling, via a plurality of magnetic field probes, a magnetic field at a boundary of a volume during a scan;
calculating the magnetic field within the volume based on the sampled magnetic field;
calculating a k-space trajectory based on the calculated magnetic field; and
reconstructing, from magnetic resonance signals acquired during the scan, an image with the k-space trajectory.

16. The method of claim 15, wherein calculating the magnetic field comprises applying a transfer function to the sampled magnetic field.

17. The method of claim 15, wherein the calculated magnetic field is expressed using cylindrical harmonics.

18. The method of claim 15, further comprising correcting the magnetic resonance signals based on the k-space trajectory, and wherein reconstructing the image comprises applying an inverse Fourier transform to the corrected magnetic resonance signals.

19. The method of claim 15, further comprising outputting the image to a display device.

20. The method of claim 15, further comprising calibrating a gradient field control based on the calculated magnetic field.
